(19) United States
(12) Patent Application Publication
(10) Pub. No.: US 2013/0011963 A1
(43) Pub. Date: Jan. 10, 2013

(54) PROCESS FOR PRODUCING ZINC OXIDE VARISTOR

(75) Inventors: Ching-Hohn LIEN, Taipei (TW); Jie-An ZHU, Shanghai (CN); Zhi-Xian XU, Guishan Shiang (TW); Hong-Zong XU, Guishan Shiang (TW); Ting-Yi FANG, Guishan Shiang (TW); Xing-Xiang HUANG, Guishan Shiang (TW)

(73) Assignee: SFI ELECTRONICS TECHNOLOGY INC., Guishan Shiang (TW)

(21) Appl. No.: 13/614,298

(22) Filed: Sep. 13, 2012

Related U.S. Application Data
(63) Continuation-in-part of application No. 12/458,369, filed on Jul. 9, 2009, now abandoned.

(51) Int. Cl. H01L 21/02

(52) U.S. Cl. 438/104; 257/E21.004

(57) ABSTRACT

A process for producing zinc oxide varistors possessed a property of breakdown voltage (V1mA) ranging from 230 to 1,730 V/mm is to perform the doping of zinc oxide and the sintering of zinc oxide grains with a high-impedance sintered powder through two independent procedures, so that the doped zinc oxide and the high-impedance sintered powder are well mixed in a predetermined ratio and then used to make the zinc oxide varistors through conventional technology by low-temperature sintering (lower than 900° C.); the resultant zinc oxide varistors may use pure silver as inner electrode and particularly possess breakdown voltage ranging from 230 to 1,730 V/mm.

### CROSS REFERENCE TO RELATED APPLICATIONS

This application is a CIP of U.S. patent application Ser. No. 12/458,369 filed Jul. 9, 2009, now pending.

### BACKGROUND OF THE INVENTION

1. Field of the Invention

The present invention relates to a process for producing zinc oxide (ZnO) varistors having a breakdown voltage (V_{1mA}) ranging from 230 to 1,730 V/mm, more particularly to an improved method of making zinc oxide (ZnO) varistors through two independent procedures to perform the doping of zinc oxide and the sintering of zinc oxide grains with a high-impedance sintered powder respectively.

2. Description of Prior Art

Traditionally, a ZnO varistor is made by sintering zinc oxide, together with other oxides, such as bismuth oxide, antimony oxide, silicon oxide, cobalt oxide, manganese oxide and chrome oxide, at a temperature higher than 1000° C. During sintering, semi-conductivity of the ZnO grains increases due to the doping of Bi, Sb, Si, Co, Mn and Cr while a high-impedance grain boundary layer of crystalline phase is deposited among the ZnO grains.

Accordingly, the conventional process for producing ZnO varistor is generally processed a single sintering procedure to accomplish the following two purposes at same time:

1) one purpose is involved for growth of ZnO grains as well as doping of ZnO with doping ions obtained from out of oxides if sintered to enhance semi-conductivity of the ZnO grains; and

2) the other purpose is involved for formation of the high-impedance grain boundaries to encapsulate the ZnO grains to endow the resultant ZnO varistors with non-ohmic characteristics, since these boundaries are responsible for blocking conduction at low voltages and are the source of the nonlinear electrical conduction at higher voltages.

But, this conventional process has its defects as follows:

1) ZnO grains are not in advance doped with applicable species and quantity of ions before ZnO varistor generally made by sintering zinc oxide together with other oxides;

2) the applicable species and quantity of ions for doping ZnO grains are relatively restricted;

3) for enhancement of semi-conductivity of the ZnO grains as well as for formation of the high-impedance grain boundaries to encapsulate the ZnO grains, the conventional process requires a relatively high sintering temperature, generally higher than 1000° C.;

4) particularly, properties of the resultant ZnO varistor, namely breakdown voltage, nonlinear coefficient, C value, leakage current, surge-absorbing ability and ESD-absorbing ability, are less adjustable intentionally in the course of making ZnO varistor; and

5) the internal electrodes of multilayer chip zinc oxide (ZnO) varistor made by conventional process, due to requiring a relatively high sintering temperature, should be used Ag/Pd alloy formed as internal electrodes, can not be used pure silver (Ag) formed as internal electrodes.

### SUMMARY OF THE INVENTION

In view of the shortcomings of the prior art, one primary objective of the present invention is to provide a process for producing zinc oxide varistors through two independent procedures to perform the doping of zinc oxide and the sintering of zinc oxide grains with a high-impedance sintered powder respectively. The process for producing zinc oxide varistors having a breakdown voltage (V_{1mA}) ranging from 230 to 1,730 V/mm, comprises:
a) individually advanced preparation of doped ZnO grains doped with one or more species of doping ions selected by a rule of intentionally controlling the advanced doped ZnO grains sufficiently semiconductorized to a preset breakdown voltage of the zinc oxide varistor capable of ranging from 230 to 1,730 V/mm;
b) individually advanced preparation of sintered powders (or glass powder) by a rule of intentionally controlling the sintered powder or glass powder sufficiently sintered to a preset breakdown voltage of the zinc oxide varistor capable of ranging from 230 to 1,730 V/mm;
c) mixing the doped ZnO grains of step a) with the sintered powders of step b) in a weight ratio ranging between 100:2 and 100:30 into a mixture, and
d) using the mixture to make zinc oxide varistors having a breakdown voltage (V_{1mA}) ranging from 230 to 1,730 V/mm through a known process suited for producing zinc oxide varistors.

By implementing the process of the present invention, species as well as quantity of the doping ions of the doped ZnO grains, and composition as well as preparation conditions of the high-impedance sintering powders (or glass powder) can be independently designed by according to desired properties and processing requirements of the resultant zinc oxide varistors, such as breakdown voltage ranging from 230 to 1,730 V/mm, nonlinear coefficient, C value, leakage current, surge-absorbing ability, ESD-absorbing ability, and permeability, or by according to preparation conditions of low-temperature sintering to realize zinc oxide varistors with various desired properties.

Hence, the process of the present invention allows enhanced adjustability to properties of the resultant zinc oxide varistors, thereby meeting diverse practical needs.

### BRIEF DESCRIPTION OF THE DRAWINGS

The invention as well as a preferred mode of use, further objectives and advantages thereof will be best understood by reference to the following detailed description of illustrative embodiments when acquire in conjunction with the accompanying drawings, wherein:

FIG. 1 shows an illustrated flow chart of the invented process for producing zinc oxide varistors having a breakdown voltage ranging from 230 to 1,730 V/mm of the present invention;

FIG. 2 shows the X-ray diffraction pattern of ZnO;

FIG. 3 shows the X-ray diffraction pattern of ZnO doped with 2 mol % of Si;

FIG. 4 shows the X-ray diffraction pattern of ZnO doped with 2 mol % of W;

FIG. 5 shows the X-ray diffraction pattern of ZnO doped with 2 mol % of V;

FIG. 6 shows the X-ray diffraction pattern of ZnO doped with 2 mol % of Fe;

FIG. 7 shows the X-ray diffraction pattern of ZnO doped with 2 mol % of Sb;

FIG. 8 shows the X-ray diffraction pattern of ZnO doped with 2 mol % of Sn;

FIG. 9 shows the X-ray diffraction pattern of ZnO doped with 2 mol % of In;

FIG. 10 shows the X-ray diffraction pattern of ZnO doped with 2 mol % of Y;

FIG. 11 is a resistance-temperature graph of Si-doped Zn-X144 sintered with 5% of G1-08 sintered powder;

FIG. 12 is a resistance-temperature graph of Ag-doped Zn-X141 sintered with 5% of G1-38 sintered powder; and

FIG. 13 is a schematic drawing showing a dual-function element made from materials of Formula A and Formula B.

### DETAILED DESCRIPTION OF THE PREFERRED EMBODIMENT

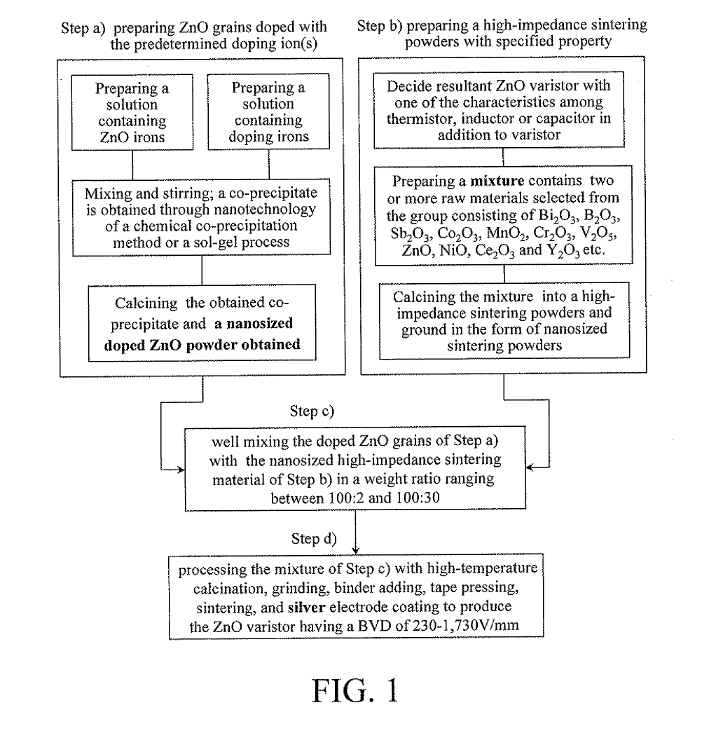

As shown in FIG. 1, a process for producing zinc oxide varistors having a breakdown voltage (V_{1mA}) ranging from 230 to 1,730 V/mm comprises the following steps:
a) individually advanced preparation of doped ZnO grains doped with one or more species of doping ions selected by a rule of intentionally controlling the advanced doped ZnO grains sufficiently semiconductorized to a preset breakdown voltage of the zinc oxide varistor capable of ranging from 230 to 1,730 V/mm;
b) individually advanced preparation of sintered powders (or glass powder) by a rule of intentionally controlling the sintered powder or glass powder sufficiently sintered to a preset breakdown voltage of the zinc oxide varistor capable of ranging from 230 to 1,730 V/mm;
c) mixing the doped ZnO grains of step a) with the sintered powders of step b) in a weight ratio ranging between 100:2 and 100:30 into a mixture, and
d) using the mixture to make zinc oxide varistors having a breakdown voltage (V_{1mA}) ranging from 230 to 1,730 V/mm through a known process suited for producing zinc oxide varistors.

More detailed is expounded hereinafter.

A. Individually Advanced Preparation of ZnO Grains Doped with Doping Ions According to a Preset Breakdown Voltage of Zinc Oxide Varistors Capable of Ranging from 230 to 1,730 V/mm;

A solution containing zinc ions and another solution containing doping ions are prepared based on the principles of crystallography. Then nanotechnology, such as the coprecipitation method or the sol-gel process, is applied to obtain a precipitate. The precipitate then undergoes thermal decomposition so that ZnO grains doped with the doping ions are obtained.

The ZnO grains may be doped with one or more species of ions selected by a rule of intentionally controlling the advanced doped ZnO grains sufficiently semiconductorized to a preset breakdown voltage of the zinc oxide varistor capable of ranging from 230 to 1,730 V/mm. Therein, quantity of the doping ion(s) is preferably less than 15 mol % of ZnO, more preferably less than 10 mol % of Zn, and most preferably less than 2 mol % of Zn.

The doping ion(s) is one or more selected from the group consisting of Ag, Li, Cu, Al, Ce, Co, Cr, In, Ga, La, Y, Nb, Ni, Pr, Sb, Se, Ti, V, W, Zr, Si, B, Fe, and Sn.

The solution containing zinc ions may be zinc acetate or zinc nitrate. The solution containing doping ions may be made by dissolving one or more species of said doping ions in acetate or nitrate.

Then the solution containing zinc ions and the solution containing doping ions are mixed and stirred to form a blended solution containing zinc ions and doping ions by means of the chemical coprecipitation method. While mixing, a surfactant or a high polymer may be added according to practical needs. Then a precipitant is added into the blended solution during stir in a co-current or counter-current manner. Through proper adjustment of the pH value of the solution, a co-precipitate is obtained. After repeatedly washed and then dried, the co-precipitate is calcined at proper temperature so that ZnO grains doped with the doping ions are obtained.

The aforementioned precipitant may be selected from the group consisting of oxalic acid, carbamide, ammonium carbonate, ammonium hydrogen carbonate, ammonia, or other alkaline solutions.

Another approach to making doped ZnO grains involves immersing fine ZnO powder into a solution containing the doping ions. After dried, the precipitate is calcined in air, or in an inter gas, such as argon gas, or in a reducing gas containing hydrogen or carbon monoxide, to form ZnO grains doped with the doping ions.

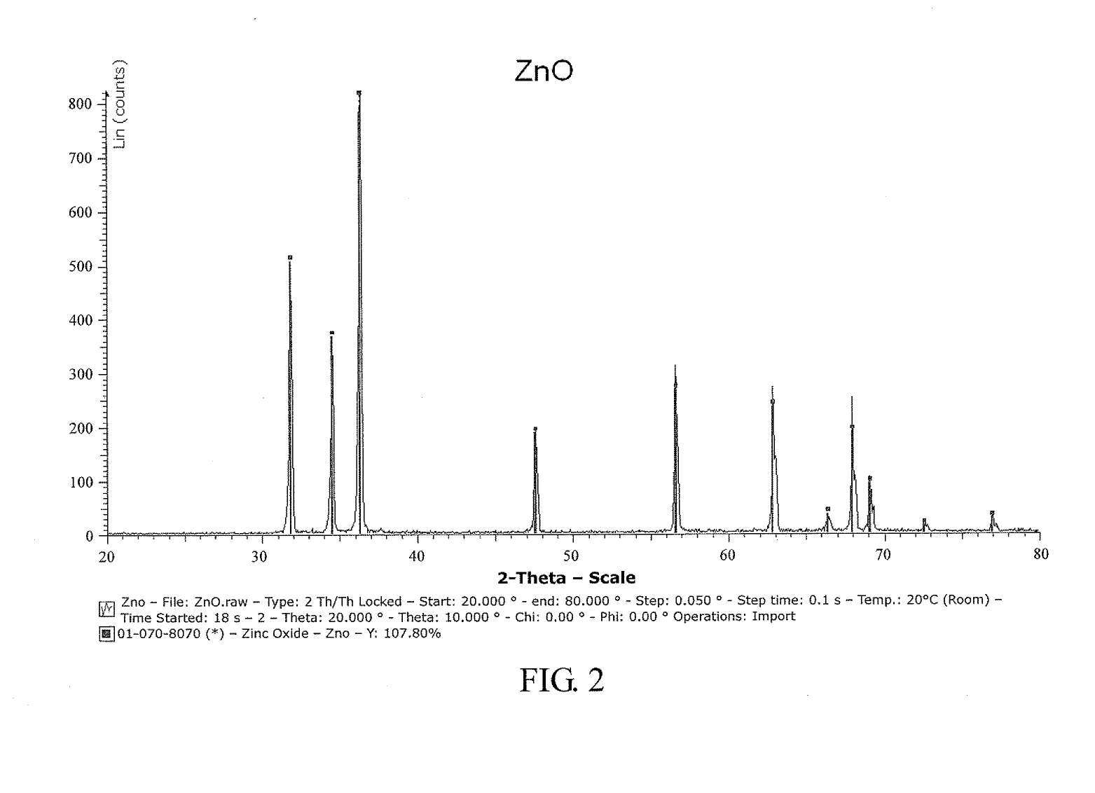

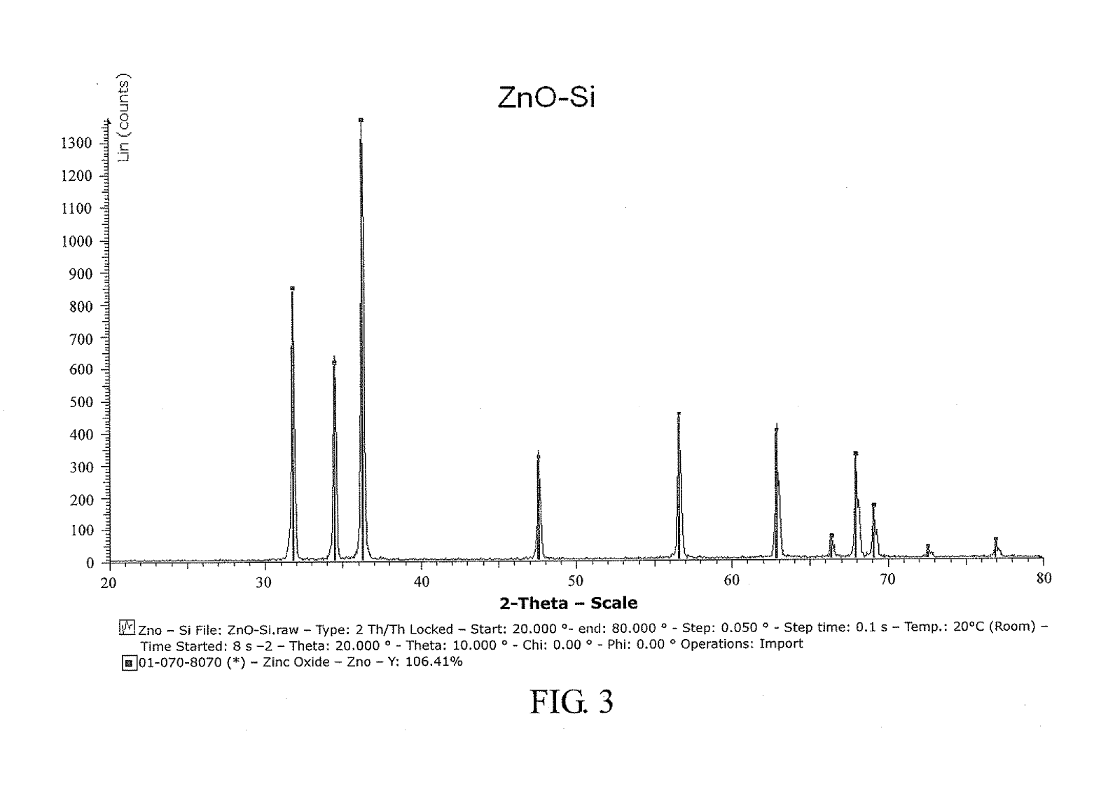

FIG. 2 is an X-ray diffraction pattern of pure ZnO grains. ZnO grains doped with 2 mol % of Si made by any of the foregoing approaches. The X-ray diffraction pattern thereof obtained by an X-ray diffractometer is shown in FIG. 3. As compared with FIG. 2 of the X-ray diffraction pattern of pure ZnO grains, FIG. 3 suggests that Si ions are fully dissolved into the lattices of the ZnO grains.

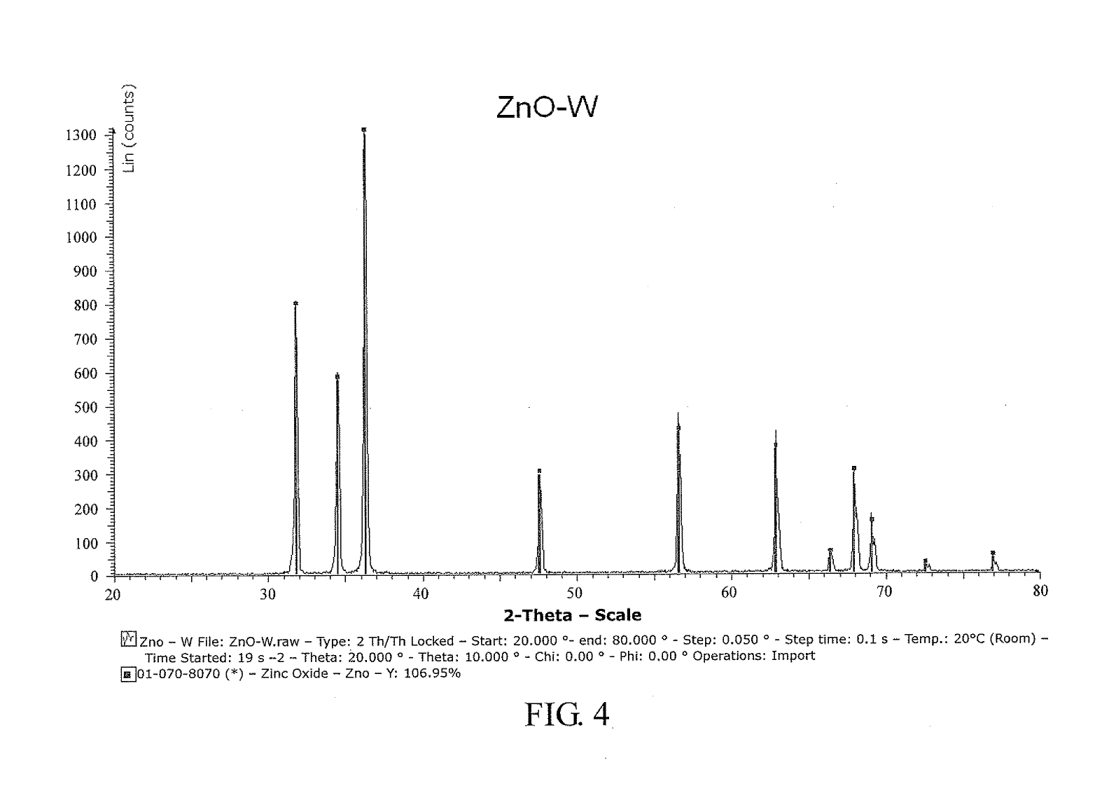

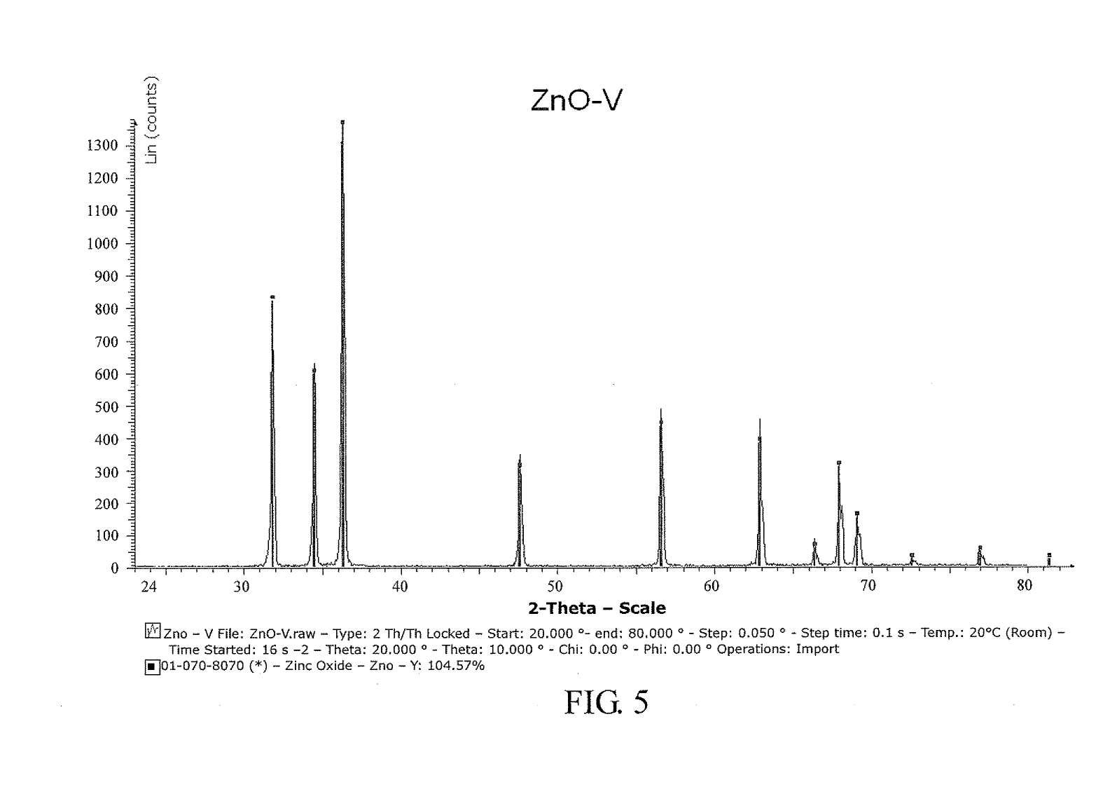

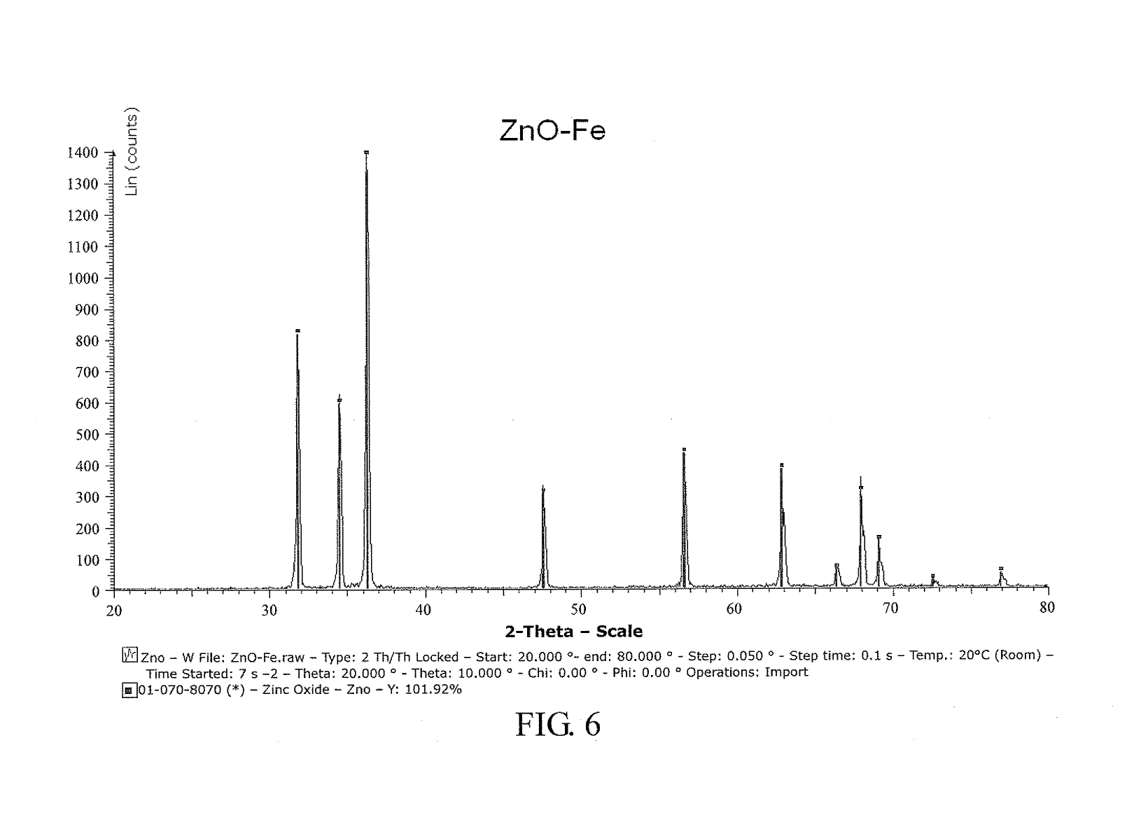

ZnO grains doped with 2 mol % of W or V or Fe ions can be obtained similarly. The X-ray diffraction patterns of the ZnO grains doped with 2 mol % of W ions, the ZnO grains doped with 2 mol % of V ions, and the ZnO grains doped with 2 mol % of Fe ions are shown in FIG. 4, FIG. 5 and FIG. 6, respectively. As compared with FIG. 2 that shows the X-ray diffraction pattern of pure ZnO grains, FIGS. 3 through 5 prove that W, V, and Fe ions are fully dissolved into the lattices of the ZnO grains.

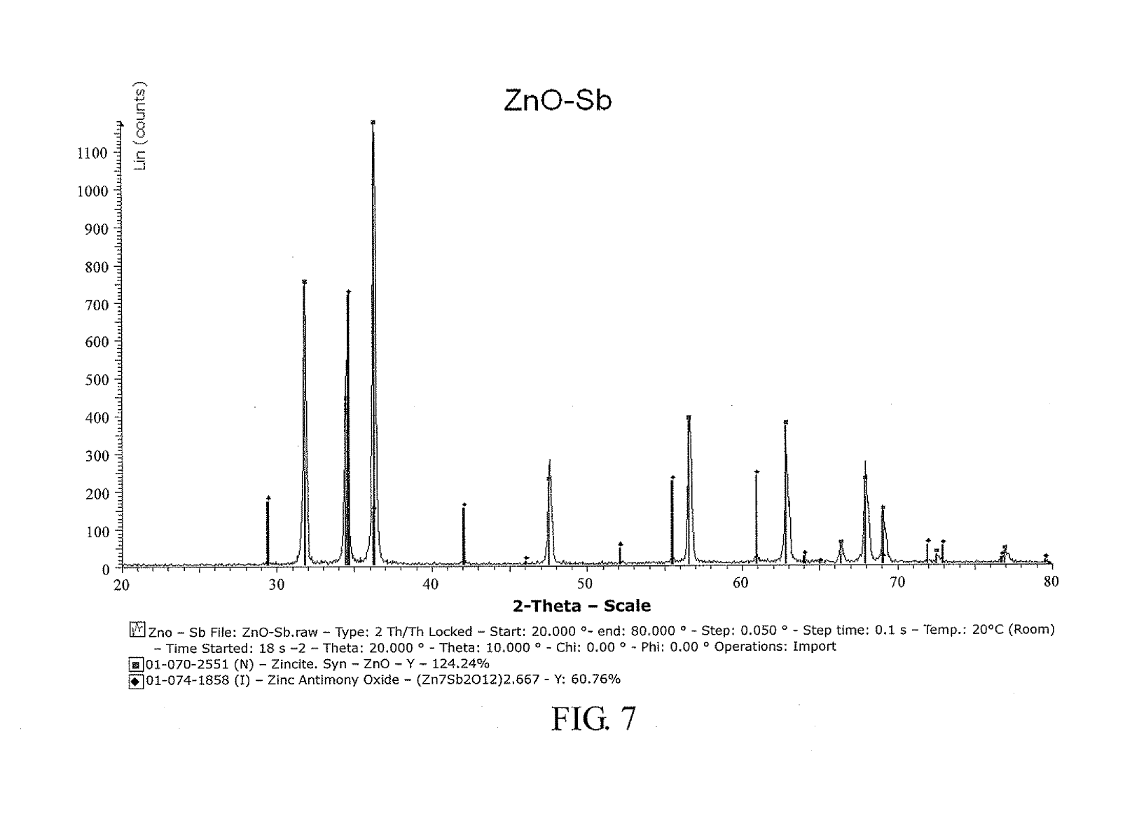

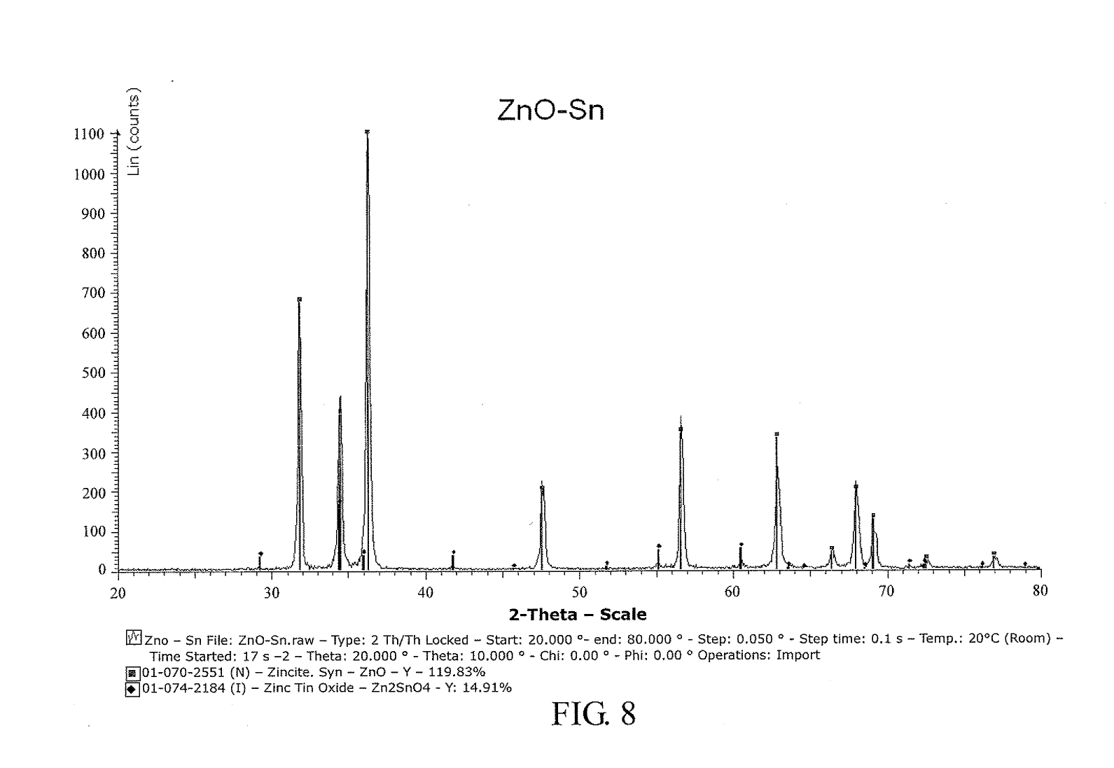

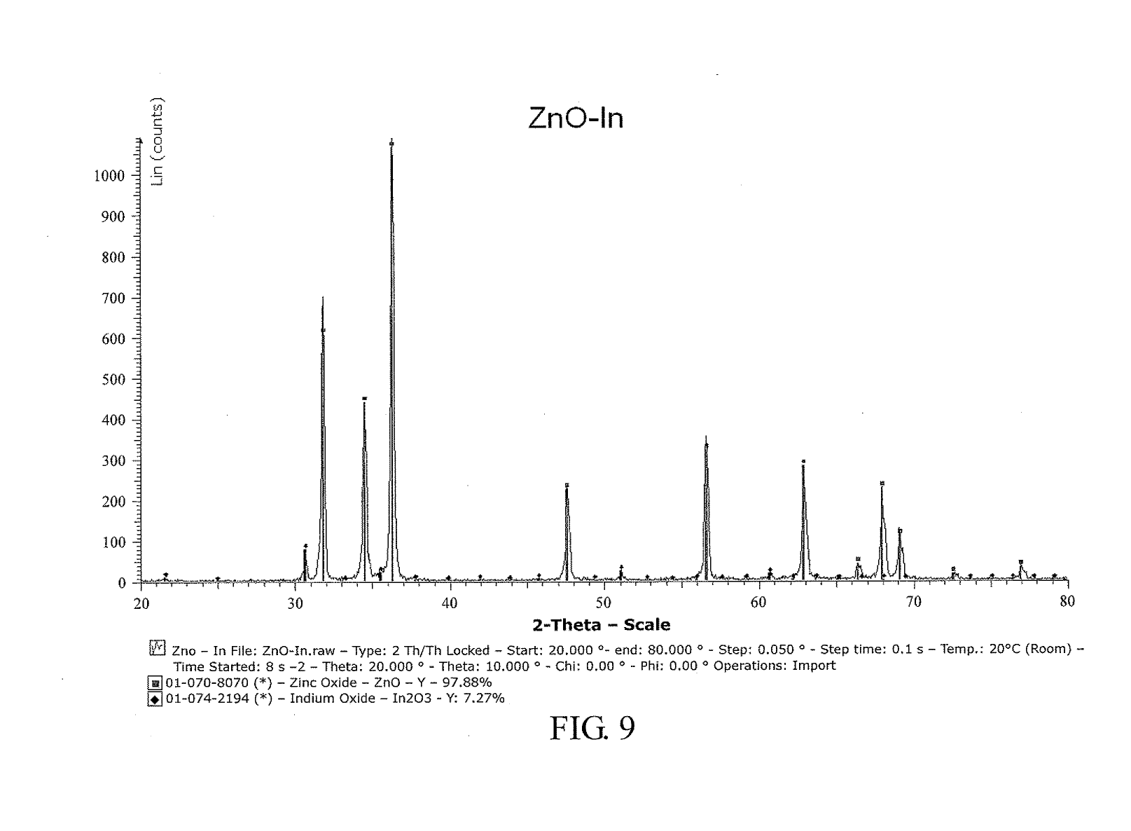

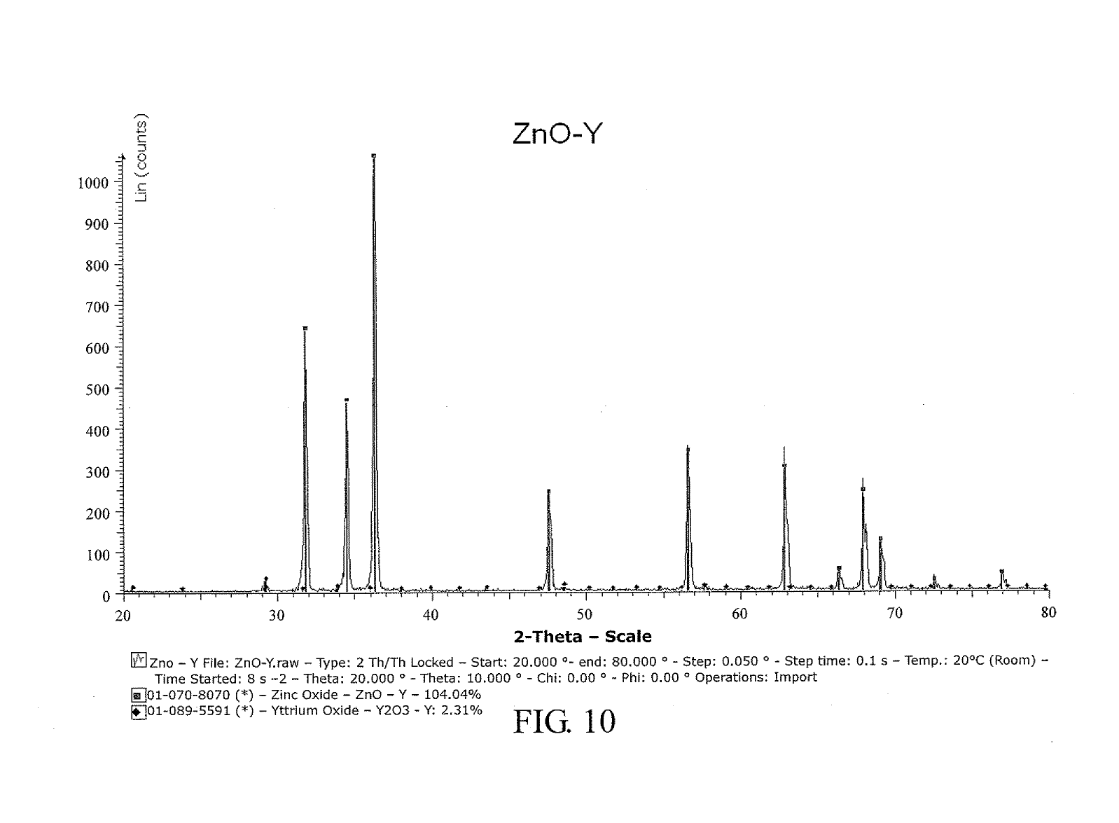

ZnO grains doped with 2 mol % of Sb, Sn, In, and Y ions, respectively, may be obtained in the same manner. FIG. 7 shows the X-ray diffraction pattern of ZnO doped with 2 mol % of Sb, FIG. 8 shows the X-ray diffraction pattern of ZnO doped with 2 mol % of Sn, FIG. 9 shows the X-ray diffraction pattern of ZnO doped with 2 mol % of In, and FIG. 10 shows the X-ray diffraction pattern of ZnO doped with 2 mol % of Y, it is indicated that Sb, Sn, In or Y ions are partially dissolved into the lattices of the ZnO grains, according to comparison between the diffraction patterns of FIGS. 6 through 9 with FIG. 2 that shows the X-ray diffraction pattern of pure ZnO grains.

Thus, in the step of preparing ZnO grains doped with doping ions, the species and quantity of the doping ions can be selected from an enlarged scope. Consequently, properties of the resultant ZnO varistors, including breakdown voltage ranging from 230 to 1,730 V/mm, nonlinear coefficient, C value, leakage current, surge-absorbing ability, and ESD-absorbing ability, can be effectively modulated.

B. Individually Advanced Preparation of Sintered Powders (or Glass Powder) According to a Preset Breakdown Voltage of the Zinc Oxide Varistor Capable of Ranging from 230 to 1,730 V/mm;

Preparing a high-impedance sintered powders or glass powders is to prepare a mixture provided with different composition of two or more oxides selected from the group consisting of Bi₂O₃, B₂O₃, Sb₂O₃, Co₂O₃, MnO₂, Cr₂O₃, V₂O₅, ZnO, NiO, SiO₂, Ce₂O₃, Y₂O₃, nickel manganese cobalt oxide and soft ferrite or any combination thereof.

The purpose of adding extra zinc oxide (ZnO) into the sintered powders or glass powders is to enhance sintering effect between grain boundaries.

The mixture of selected oxides is made by a series of processing procedures, including mixing, calcination and grinding, and finally is ground into fine powder, preferably into nanosized powder, to form as the sintering powders or glass powders.

Alternatively, nanotechnology is implemented to turn oxides with different compositions into nanosized sintered powders or nanosized glass powder.

In the step of preparing the sintered powders or glass powders, the oxides are capably selected by a rule of according to a preset breakdown voltage of the zinc oxide varistor capable of ranging from 230 to 1,730 V/mm. Moreover, the sintered powders or glass powders are capably selected to endow the ZnO varistors with thermistor properties, inductor properties, capacitor properties, etc., in addition to varistor properties.

For example, when the resultant ZnO varistor is desired to have additional thermistor properties, the sintered powders or glass powders may be nickel manganese cobalt oxide. When the resultant ZnO varistor is desired to have additional inductor properties, the sintered powder or glass powder may be soft ferrite. When the resultant ZnO varistor is desired to have additional capacitor properties, the sintered powder or glass powder may be titanate of high dielectric constant.

C. Well Mixing ZnO Grains with High-Impedance Sintered Powders or Glass Powders in a Specific Ratio to Produce a Mixture for Making the Zinc Oxide Varistor;

The ZnO grains of Step a) mentioned above and the high-impedance sintered powder or glass powder of Step b) mentioned above are properly made according to the desired properties of the resultant ZnO varistors. Then the ZnO grains and the sintered powder or glass powder are well mixed in a weight ratio the preferably ranging between 100:2 and 100:30, and more preferably ranging between 100:5 and 100:15.

D. Processing the Mixture to Produce ZnO Varistors Having a Breakdown Voltage Ranging from 230 to 1,730 V/mm in Advance Controlled in Previous Procedures;

At last, the mixture as the product of Step c) mentioned above is processed with high-temperature calcination, grinding, binder adding, tape pressing, sintering, and silver electrode coating to produce the resultant ZnO varistors. Therein, the calcination temperature is desirably ranging between 950° C.±10° C. and 1100° C.±10° C.

Some embodiments will be later explained for proving the process for producing zinc oxide varistors having a breakdown voltage ranging from 230 to 1,730 V/mm of the present invention possesses the following features:
1. The varistor properties of the resultant ZnO varistors, including breakdown voltage having a breakdown voltage ranging from 230 to 1,730 V/mm, nonlinear coefficient, C value, leakage current, surge-absorbing ability, and ESD-absorbing ability, can be changed or adjusted by selecting the species of the ions doping the ZnO grains or by modulating the weight ratio between the ZnO grains and the high-impedance sintered powder.
2. The varistor properties of the resultant ZnO varistors can be changed or adjusted by changing the quantity of the ions doping the ZnO grains.
3. The varistor properties of the resultant ZnO varistors can be changed or adjusted by doping the ZnO grains with at least two species of doping ions or by controlling the sintering temperature.
4. The varistor properties of the resultant ZnO varistors can be changed or adjusted by modifying the composition of the sintered powder or glass powder.
5. By using ZnO grains doped with appropriate doping ions and by modifying the composition of the sintered powder, it is possible to have pure silver made as inner electrode and produce ZnO varistors possessing excellent varistor properties through low-temperature sintering.
6. By using sintered powders of different formulas, it is possible to produce a dual-function element having varistor properties and thermistor properties. For instance, the resultant ZnO varistor may possess varistor properties and thermistor properties at the same time, or may possess varistor properties and inductor properties at the same time, or may possess varistor properties and capacitor properties at the same time.

### Example 1

The chemical coprecipitation method was used to prepare sample ZnO grains doped with 1 mol % of different single species of ions and a sintered powder numbered G1-00, which has the composition as provided below.

| Sintered | Composition (wt %) | | | | | | |
|---|---|---|---|---|---|---|---|
| powder | ZnO | SiO₂ | B₂O₃ | Bi₂O₃ | Co₂O₃ | MnO₂ | Cr₂O₃ |
| G1-00 | 8 | 23 | 19 | 27 | 8 | 8 | 7 |

The sample ZnO grains and G1-00 sintered powders were well mixed in a weight ratio of 100:10 or 100:15 or 100:30, and then pressed into sinter cakes under 1000 kg/cm². The sinter cakes were sintered at 1065° C. for two hours, and got silver electrode formed thereon at 800° C. At last, the sintered product with silver electrode was made into round ZnO varistors. The varistors were tested on their varistor properties and the results are listed in Table 1.

From Table 1, it is learned that when the same sintered powder is used, the varistors have their varistor properties varying with the species of the doping ions doped in the ZnO grains. For example, the breakdown voltage, abbreviated as “BDV”, may range from 230 to 1730 V/mm. Similarly, when the ZnO grains doped with the same doping ions, the varistors have their varistor properties varying with the mix ratio between the ZnO grains and the high-impedance sintered powder.

Thus, the varistor properties of the ZnO varistor can be modified or adjusted by changing the species of the doping ions doped in ZnO grains or the mix ratio between the ZnO grains and the high-impedance sintered powder.

TABLE 1
Properties of ZnO Varistors Made of ZnO Grains Doped with Different Single Species of Doping
Ions and the Same Sintered powder in Different Ratios

| | | Silver/ | | | | | | |
|---|---|---|---|---|---|---|---|---|
| | | Reduction | Green Size | Grog Size | BDV | | I_{L} | Cp |
| No. | Composition | (° C.) | (mm) | (mm) | (V/mm) | α | (μA) | (pF) |
| 1 | Zn—Ce + 10% G1-00 | 7472/845° C. | 8.4 × 1.08 | 7.12 × 0.90 | 392 | 21 | 25 | 253 |
| 2 | Zn—Ce + 15% G1-00 | 7472/845° C. | 8.4 × 1.09 | 7.14 × 0.87 | 386 | 22 | 27 | 228 |
| 3 | Zn—Co + 10% G1-00 | 7472/845° C. | 8.4 × 1.12 | 7.21 × 0.93 | 441 | 22 | 20 | 205 |
| 4 | Zn—Co + 15% G1-00 | 7472/845° C. | 8.4 × 1.12 | 7.25 × 0.95 | 435 | 22 | 28 | 193 |
| 5 | Zn—Ni + 10% G1-00 | 7472/845° C. | 8.4 × 1.18 | 7.17 × 0.98 | 451 | 20 | 29 | 208 |
| 6 | Zn—Ni + 15% G1-00 | 7472/845° C. | 8.4 × 1.18 | 7.21 × 0.97 | 437 | 21 | 32 | 178 |
| 7 | Zn—Al + 10% G1-00 | 7472/845° C. | 8.4 × 1.18 | 7.06 × 0.96 | 395 | 7 | 187 | 293 |
| 8 | Zn—Al + 15% G1-00 | 7472/845° C. | 8.4 × 1.18 | 7.10 × 0.97 | 348 | 8 | 157 | 283 |
| 9 | Zn—Al + 30% G1-00 | 7472/845° C. | 8.4 × 1.18 | 7.10 × 0.97 | 320 | 14 | 65 | 31 |
| 10 | Zn—Sb + 10% G1-00 | 7472/845° C. | 8.4 × 1.18 | 7.01 × 0.93 | 809 | 29 | 7.2 | 127 |
| 11 | Zn—Sb + 15% G1-00 | 7472/845° C. | 8.4 × 1.18 | 7.08 × 0.92 | 807 | 31 | 10 | 105 |
| 12 | Zn—Cu + 10% G1-00 | 7472/845° C. | 8.4 × 1.17 | 7.13 × 1.03 | 447 | 11 | 84 | 270 |
| 13 | Zn—Cu + 15% G1-00 | 7472/845° C. | 8.4 × 1.17 | 7.17 × 0.96 | 470 | 13 | 72 | 238 |
| 14 | Zn—Pr + 10% G1-00 | 7472/845° C. | 8.4 × 1.19 | 7.03 × 0.95 | 356 | 20 | 24 | 259 |
| 15 | Zn—Pr + 15% G1-00 | 7472/845° C. | 8.4 × 1.19 | 7.09 × 0.98 | 311 | 23 | 19 | 237 |
| 16 | Zn—Se + 10% G1-00 | 7472/845° C. | 8.4 × 1.12 | 7.17 × 0.93 | 399 | 20 | 34 | 284 |
| 17 | Zn—Se + 15% G1-00 | 7472/845° C. | 8.4 × 1.12 | 7.19 × 0.92 | 372 | 21 | 33 | 243 |
| 18 | Zn—Fe + 10% G1-00 | 7472/845° C. | 8.4 × 1.14 | 7.22 × 0.94 | 230 | 10 | 87 | 557 |
| 19 | Zn—Fe + 15% G1-00 | 7472/845° C. | 8.4 × 1.14 | 7.18 × 0.91 | 251 | 13 | 55 | 386 |
| 20 | Zn—Cr + 10% G1-00 | 7472/845° C. | 8.4 × 1.08 | 7.22 × 0.88 | 566 | 20 | 28 | 185 |
| 21 | Zn—Cr + 15% G1-00 | 7472/845° C. | 8.4 × 1.08 | 7.21 × 0.90 | 526 | 22 | 28 | 152 |
| 22 | Zn—Nb + 10% G1-00 | 7472/845° C. | 8.4 × 1.10 | 7.14 × 0.89 | 392 | 12 | 77 | 319 |
| 23 | Zn—Nb + 15% G1-00 | 7472/845° C. | 8.4 × 1.10 | 7.17 × 0.92 | 399 | 15 | 60 | 265 |
| 24 | Zn—V + 10% G1-00 | 7472/845° C. | 8.4 × 1.07 | 7.59 × 0.91 | 445 | 17 | 46 | 236 |
| 25 | Zn—V + 15% G1-00 | 7472/845° C. | 8.4 × 1.07 | 7.53 × 0.90 | 417 | 18 | 45 | 215 |
| 26 | Zn—La + 10% G1-00 | 7472/845° C. | 8.4 × 1.13 | 7.09 × 0.94 | 431 | 14 | 46 | 230 |
| 27 | Zn—La + 15% G1-00 | 7472/845° C. | 8.4 × 1.13 | 7.11 × 0.95 | 424 | 15 | 46 | 213 |
| 28 | Zn—Ti + 10% G1-00 | 7472/845° C. | 8.4 × 1.16 | 7.06 × 0.98 | 424 | 10 | 100 | 239 |
| 29 | Zn—Ti + 15% G1-00 | 7472/845° C. | 8.4 × 1.16 | 7.10 × 0.96 | 421 | 14 | 64 | 200 |
| 30 | Zn—Sn + 10% G1-00 | 7472/845° C. | 8.4 × 1.19 | 6.96 × 0.99 | 775 | 28 | 6.6 | 99 |
| 30a | Zn—Sn + 15% G1-00 | 7472/845° C. | 8.4 × 1.19 | 7.02 × 0.93 | 773 | 27 | 11 | 98 |
| 31 | Zn—Sn + 30% G1-00 | 7472/845° C. | 8.4 × 1.19 | 7.02 × 0.93 | 758 | 25 | 14 | 103 |
| 32 | Zn—Li + 10% G1-00 | 7472/845° C. | 8.4 × 1.15 | 7.21 × 0.94 | 434 | 18 | 38 | 237 |
| 33 | Zn—Li + 15% G1-00 | 7472/845° C. | 8.4 × 1.15 | 7.22 × 0.90 | 414 | 20 | 33 | 196 |
| 34 | Zn—Ag—W + 10% G1-00 | 7472/845° C. | 8.4 × 1.11 | 7.40 × 0.92 | 380 | 17 | 41 | 280 |
| 35 | Zn—Ag—W + 15% G1-00 | 7472/845° C. | 8.4 × 1.11 | 7.38 × 0.92 | 354 | 17 | 42 | 234 |
| 36 | Zn—Zr + 10% G1-00 | 7472/845° C. | 8.4 × 1.17 | 7.09 × 0.97 | 457 | 13 | 68 | 237 |
| 37 | Zn—Zr + 15% G1-00 | 7472/845° C. | 8.4 × 1.17 | 7.13 × 0.94 | 440 | 15 | 59 | 205 |
| 38 | Zn—W + 10% G1-00 | 7472/845° C. | 8.4 × 1.07 | 7.28 × 0.91 | 465 | 14 | 60 | 277 |
| 39 | Zn—W + 15% G1-00 | 7472/845° C. | 8.4 × 1.07 | 7.28 × 0.91 | 445 | 15 | 55 | 210 |
| 40 | Zn—Si + 10% G1-00 | 7472/845° C. | 8.4 × 1.17 | 7.11 × 0.95 | 282 | 22 | 16 | 316 |
| 41 | Zn—Si + 15% G1-00 | 7472/845° C. | 8.4 × 1.17 | 7.14 × 0.93 | 272 | 22 | 14 | 248 |
| 42 | Zn—In + 10% G1-00 | 7472/845° C. | 8.4 × 1.23 | 6.85 × 0.97 | 1730 | 10 | 54 | 36 |
| 43 | Zn—In + 15% G1-00 | 7472/845° C. | 8.4 × 1.23 | 6.91 × 1.00 | 1409 | 9 | 100 | 43 |
| 44 | Zn—Ag + 10% G1-00 | 7472/845° C. | 8.4 × 1.13 | 7.22 × 0.94 | 386 | 21 | 28 | 276 |
| 45 | Zn—Ag + 15% G1-00 | 7472/845° C. | 8.4 × 1.13 | 7.25 × 0.94 | 356 | 22 | 28 | 237 |

### Example 2

The chemical coprecipitation method was used to prepare sample ZnO grains doped with different quantity of the same single species of doping ions. The sintered powder G1-00 of Example 1 was also used.

The sample ZnO grains and the sintered powder G1-00 were well mixed in a weight ratio of 100:10 and then the mixture was used to make round ZnO varistors under the same conditions as provided in Example 1. The varistors were tested on their varistor properties and the results are listed in Table 2.

From Table 2, the ZnO varistors have breakdown voltages ranged from 238 to 683 V/mm, it is learned that when the ZnO grains is doped with the same doping ions and then mixed with the same sintered powder, the varistors have their varistor properties varying with the quantitative variation of the doping ions doped in ZnO grains.

Thus, the varistor properties of the ZnO varistor can be adjusted by controlling the quantity of the doping ions doped in ZnO grains.

TABLE 2
Properties of ZnO Varistors Made of ZnO Grains Doped with the Same Single Species of Doping
Ions in Different Quantity and the Same Sintered powder

| | | Sinter | Silver/ | Green | | | | | | |
|---|---|---|---|---|---|---|---|---|---|---|
| | | Temp. | Reduction | Size | Grog Size | BDV | | I_{L} | Cp | |
| No. | Composition | (° C.) | (° C.) | (mm) | (mm) | (V/mm) | α | (μA) | (pF) | Clamp |
| 46 | Zn—0.5% Ni + | 1065 | 7472/845° C. | 8.4 × 1.13 | 7.07 × 0.90 | 298 | 24 | 8.2 | 325 | 1.81 |
| | 10% G1-00 | | | | | | | | | |
| 47 | Zn—1.0% Ni + | 1065 | 7472/845° C. | 8.4 × 1.15 | 6.99 × 0.93 | 291 | 24 | 9.2 | 304 | 1.92 |
| | 10% G1-00 | | | | | | | | | |
| 48 | Zn—1.5% Ni + | 1065 | 7472/845° C. | 8.4 × 1.14 | 7.03 × 0.91 | 326 | 24 | 9.7 | 304 | 1.84 |
| | 10% G1-00 | | | | | | | | | |
| 49 | Zn—0.5% Sn + | 1065 | 7472/845° C. | 8.4 × 1.27 | 6.72 × 0.89 | 683 | 31 | 3.6 | 145 | 1.66 |
| | 10% G1-00 | | | | | | | | | |
| 50 | Zn—1.0% Sn + | 1065 | 7472/845° C. | 8.4 × 1.27 | 6.67 × 1.02 | 669 | 30 | 10 | 125 | 1.70 |
| | 10% G1-00 | | | | | | | | | |
| 51 | Zn—1.5% Sn + | 1065 | 7472/845° C. | 8.4 × 1.26 | 6.75 × 0.98 | 661 | 33 | 4 | 111 | 1.65 |
| | 10% G1-00 | | | | | | | | | |
| 52 | Zn—0.5% Li + | 1065 | 7472/845° C. | 8.4 × 1.14 | 7.02 × 0.92 | 258 | 24 | 7.7 | 292 | 1.83 |
| | 10% G1-00 | | | | | | | | | |
| 53 | Zn—1.0% Li + | 1065 | 7472/845° C. | 8.4 × 1.14 | 7.00 × 0.93 | 251 | 24 | 6.8 | 255 | 1.87 |
| | 10% G1-00 | | | | | | | | | |
| 54 | Zn—1.5% Li + | 1065 | 7472/845° C. | 8.4 × 1.14 | 7.03 × 0.93 | 265 | 24 | 6.6 | 273 | 1.87 |
| | 10% G1-00 | | | | | | | | | |
| 55 | Zn—0.5% Sb + | 1065 | 7472/845° C. | 8.4 × 1.17 | 6.91 × 0.95 | 575 | 29 | 3.7 | 130 | 1.70 |
| | 10% G1-00 | | | | | | | | | |
| 56 | Zn—1.0% Sb + | 1065 | 7472/845° C. | 8.4 × 1.17 | 6.76 × 0.97 | 659 | 31 | 3.3 | 97 | 1.62 |
| | 10% G1-00 | | | | | | | | | |
| 57 | Zn—1.5% Sb + | 1065 | 7472/845° C. | 8.4 × 1.20 | 6.81 × 0.96 | 596 | 32 | 2.6 | 94 | 1.57 |
| | 10% G1-00 | | | | | | | | | |
| 58 | Zn—0.5% Pr + | 1065 | 7472/845° C. | 8.4 × 1.26 | 6.75 × 1.01 | 310 | 24 | 6 | 243 | 1.86 |
| | 10% G1-00 | | | | | | | | | |
| 59 | Zn—1.0% Pr + | 1065 | 7472/845° C. | 8.4 × 1.20 | 6.91 × 0.95 | 356 | 25 | 6.8 | 249 | 1.81 |
| | 10% G1-00 | | | | | | | | | |
| 60 | Zn—1.5% Pr + | 1065 | 7472/845° C. | 8.4 × 1.21 | 6.84 × 0.98 | 337 | 25 | 6.8 | 233 | 1.80 |
| | 10% G1-00 | | | | | | | | | |
| 61 | Zn—0.5% Ag + | 1065 | 7472/845° C. | 8.4 × 1.14 | 7.01 × 0.96 | 275 | 24 | 6.9 | 259 | 1.83 |
| | 10% G1-00 | | | | | | | | | |
| 62 | Zn—1.0% Ag + | 1065 | 7472/845° C. | 8.4 × 1.19 | 6.97 × 0.98 | 265 | 25 | 8.9 | 258 | 1.77 |
| | 10% G1-00 | | | | | | | | | |
| 63 | Zn—1.5% Ag + | 1065 | 7472/845° C. | 8.4 × 1.18 | 6.99 × 0.97 | 239 | 24 | 9.1 | 305 | 1.76 |
| | 10% G1-00 | | | | | | | | | |
| 64 | Zn—0.5% Si + | 1065 | 7472/845° C. | 8.4 × 1.16 | 7.02 × 0.93 | 277 | 24 | 10 | 305 | 1.78 |
| | 10% G1-00 | | | | | | | | | |
| 65 | Zn—1.0% Si + | 1065 | 7472/845° C. | 8.4 × 1.14 | 7.13 × 0.92 | 312 | 24 | 13 | 277 | 1.73 |
| | 10% G1-00 | | | | | | | | | |
| 66 | Zn—1.5% Si + | 1065 | 7472/845° C. | 8.4 × 1.19 | 6.92 × 0.94 | 238 | 24 | 11 | 358 | 1.86 |
| | 10% G1-00 | | | | | | | | | |
| 67 | Zn—0.5% V + | 1065 | 7472/845° C. | 8.4 × 1.12 | 7.09 × 0.92 | 266 | 26 | 10 | 290 | 1.63 |
| | 10% G1-00 | | | | | | | | | |
| 68 | Zn—1.0% V + | 1065 | 7472/845° C. | 8.4 × 1.04 | 7.41 × 0.90 | 247 | 24 | 10 | 286 | 1.90 |
| | 10% G1-00 | | | | | | | | | |
| 69 | Zn—1.5% V + | 1065 | 7472/845° C. | 8.4 × 1.06 | 7.40 × 0.91 | 270 | 23 | 10 | 263 | 1.86 |
| | 10% G1-00 | | | | | | | | | |

### Example 3

The chemical coprecipitation method was used to prepare sample ZnO grains doped with at least two species of doping ions as shown in Table 3. The sintered powder G1-00 of Example 1 was also used.

The sample ZnO grains and the sintered powder G1-00 were well mixed in a weight ratio of 100:10 and then the mixture was used to make ZnO varistors under the same conditions as provided in Example 1. The varistors were tested on their varistor properties and the results are listed in Table 3.

From Table 3, the ZnO varistors have breakdown voltages ranged from 234 to 1,354 V/mm, it is learned that when the sample ZnO grains doped with at least two species of doping ions and mixed with the same sintered powder, the varistors have their varistor properties varying with the species of the doping ions doped in the ZnO grains. Meantime, the varistors also have their varistor properties varying with variation of the sintering temperature.

Thus, the varistor properties of the ZnO varistor can be adjusted in an enlarged range by changing the species of the doping ions doped in the ZnO grains or by controlling the sintering temperature.

TABLE 3
Varistor Properties of ZnO Varistors Made of ZnO Grains Doped with at least Two Species of
Single Doping Ions and the Same Sintered powder

| | | Sinter | Silver/ | Green | | | | | | |
|---|---|---|---|---|---|---|---|---|---|---|
| | | Temp. | Reduction | Size | Grog Size | BDV | | I_{L} | Cp | |
| No. | Composition | (° C.) | (° C.) | (mm) | (mm) | (V/mm) | α | (μA) | (pF) | Clamp |
| 70 | Zn—1% Si—0.5% Pr + | 1065 | 7472/845 | 8.4 × 1.20 | 6.80 × 0.93 | 261 | 26 | 3.2 | 348 | 1.69 |
| | 10% G1-00 | | | | | | | | | |
| 71 | Zn—1% Si—0.5% | 1065 | 7472/845 | 8.4 × 1.23 | 6.70 × 0.97 | 691 | 29 | 1.9 | 99 | 1.33 |
| | Sn—0.5% Sb + | | | | | | | | | |
| | 10% G1-00 | | | | | | | | | |
| 72 | Zn—1% Si—0.5% | 1107 | 7472/845 | 8.4 × 1.23 | 6.69 × 0.96 | 580 | 35 | 2.7 | 150 | 1.49 |
| | Sn—0.5% Sb + | | | | | | | | | |
| | 10% G1-00 | | | | | | | | | |
| 73 | Zn—1% Si—13.5% | 1065 | 7472/845 | 8.4 × 1.23 | 6.82 × 1.03 | 1354 | 39 | 23 | 78 | 1.43 |
| | Sn—1.5% Sb + | | | | | | | | | |
| | 10% G1-00 | | | | | | | | | |
| 74 | Zn—1% Si—13.5% | 1107 | 7472/845 | 8.4 × 1.23 | 6.75 × 1.00 | 1138 | 37 | 207 | 132 | 1.52 |
| | Sn—1.5% Sb + | | | | | | | | | |
| | 10% G1-00 | | | | | | | | | |
| 75 | Zn—1% Si—0.5% | 1065 | 7472/845 | 8.4 × 1.23 | 6.8 × 0.98 | 234 | 25 | 8.7 | 382 | 1.75 |
| | Pr—0.5% Li + | | | | | | | | | |
| | 10% G1-00 | | | | | | | | | |
| 76 | Zn—1% Si—0.5% Pr + | 1065 | 7472/845 | 8.4 × 1.23 | 6.80 × 0.98 | 242 | 26 | 4.6 | 374 | 1.80 |
| | 10% G1-00 | | | | | | | | | |
| 77 | Zn—1% Si—0.5% | 1065 | 7472/845 | 8.4 × 1.31 | 6.72 × 0.98 | 583 | 34 | 8.1 | 135 | 1.48 |
| | Sn—0.5% Sb + | | | | | | | | | |
| | 10% G1-00 | | | | | | | | | |
| 78 | Zn—1% Si—0.5% | 1107 | 7472/845 | 8.4 × 1.31 | 6.70 × 0.92 | 602 | 32 | 14 | 122 | 1.53 |
| | Sn—0.5% Sb + | | | | | | | | | |
| | 10% G1-00 | | | | | | | | | |

### Example 4

The chemical coprecipitation method was used to prepare sample ZnO grains coded Zn-X29 and Zn-X36, as shown in Table 4. The compositions of Zn-X29 and Zn-X36 are given below:

| | | | | | | | | | |
|---|---|---|---|---|---|---|---|---|---|
| Composition | ZnO | V | Mn | Cr | Co | Si | B | Pr | Ag |

Zn-X29 ZnO Grain

| | | | | | | | | | |
|---|---|---|---|---|---|---|---|---|---|
| mol % | 93 | 2 | 0.5 | 1 | 1 | 1.5 | 0.4 | 0.3 | 0.5 |

Zn-X36 ZnO Grain

| | | | | | | | | | |
|---|---|---|---|---|---|---|---|---|---|
| mol % | 100 | 2 | 0.5 | 0.5 | 0.5 | — | — | — | — |

The chemical coprecipitation method was used to prepare sintered powders numbered G1-00, G1-01, and G1-02, as shown in Table 4.

Compositions of the sintered powders G1-00, G1-01, and G1-02 are given below:

| Sintered | Composition (wt %) | | | | | | |
|---|---|---|---|---|---|---|---|
| powder | ZnO | SiO₂ | B₂O₃ | Bi₂O₃ | Co₂O₃ | MnO₂ | Cr₂O₃ |
| G1-00 | 8 | 23 | 19 | 27 | 8 | 8 | 7 |
| G1-01 | 10 | 22 | 19 | 26 | 8 | 8 | 7 |
| G1-02 | 12 | 21 | 19 | 25 | 8 | 8 | 7 |

The sample ZnO grains and sintered powders were well mixed in a weight ratio of 100:10 and then the mixture were used to make ZnO varistors under the same conditions as provided in Example 1. The varistors were tested on their varistor properties and the results are listed in Table 4.

From Table 4, the ZnO varistors have breakdown voltages ranged from 311 to 414V/mm, it is learned that sintered powders significantly affect the varistor properties of the ZnO varistors.

For example, different sintered powders lead to very different levels of surge-absorbing ability of the ZnO varistors.

Thus, the varistor properties of the ZnO varistor can be adjusted in an enlarged range by changing the sintered powder mixed with the ZnO grains.

TABLE 4
Varistor Properties of ZnO Varistors Made of ZnO Grains Doped with the
Same Species of Doping Ions and Different Sintered powders

| | | Sinter | Silver/ | Green | | | | | | |
|---|---|---|---|---|---|---|---|---|---|---|
| | | Temp. | Reduction | Size | Grog Size | BDV | | I_{L} | Cp | Surge |
| No. | Composition | (° C.) | (° C.) | (mm) | (mm) | (V/mm) | α | (μA) | (pF) | (A) |
| 79 | Zn-X29 + | 1065 | 7472/845 | 8.4 × 1.47 | 6.55 × 1.03 | 390 | 21 | 9 | 124 | 80 |
| | 10% G1-00 | | | | | | | | | |
| 80 | Zn-X29 + | 1065 | 7472/845 | 8.4 × 1.24 | 6.48 × 0.94 | 414 | 27 | 4.6 | 185 | 220 |
| | 10% G1-01 | | | | | | | | | |
| 81 | Zn-X29 + | 1065 | 7472/845 | 8.4 × 1.22 | 6.58 × 0.91 | 357 | 26 | 7 | 220 | 300 |
| | 10% G1-02 | | | | | | | | | |
| 82 | Zn-X36 + | 1065 | 7472/845 | 8.4 × 1.37 | 6.76 × 1.01 | 311 | 17 | 42 | 263 | 350 |
| | 10% G1-00 | | | | | | | | | |
| 83 | Zn-X36 + | 1065 | 7472/845 | 8.4 × 1.20 | 6.73 × 0.93 | 331 | 22 | 15 | 297 | 120 |
| | 10% G1-01 | | | | | | | | | |
| 84 | Zn-X36 + | 1065 | 7472/845 | 8.4 × 1.18 | 6.82 × 4.89 | 348 | 20 | 27 | 297 | 300 |
| | 10% G1-02 | | | | | | | | | |

### Example 5

The chemical coprecipitation method was used to prepare sample ZnO grains coded Zn-X41, Zn-X72, and Zn-X73, as shown in Table 5. Compositions of Zn-X41, Zn-X72, and Zn-X73 are given below:

| | | | | | | | |
|---|---|---|---|---|---|---|---|
| Composition | ZnO | Mn | Cr | Co | Si | Sb | Ag |

Zn-X41 ZnO Grain

| | | | | | | | | |
|---|---|---|---|---|---|---|---|---|
| | | | | | | | Pr | |
| mol % | 92.3 | 1.5 | 0.5 | 1.0 | 1.0 | 2.0 | 0.2 | 1.5 |

Zn-X72 ZnO Grain

| | | | | | | | | |
|---|---|---|---|---|---|---|---|---|
| | | | | | | | Bi | |
| mol % | 93.0 | 1.0 | 1.0 | 2.0 | — | 2.0 | 1.0 | — |

Zn-X73 ZnO Grain

| | | | | | | | | |
|---|---|---|---|---|---|---|---|---|
| mol % | 92.3 | 0.5 | 1.0 | 1.0 | 1.5 | 2.0 | 1.5 | — |

The chemical coprecipitation method was used to prepare sintered powders numbered G1-08 and G1-11, as shown in Table 5. The compositions of sintered powders G1-08 and G1-11 are given below:

| | Composition (wt %) | | | | | | | |
|---|---|---|---|---|---|---|---|---|
| Sintered powder | ZnO | SiO₂ | B₂O₃ | Bi₂O₃ | Co₂O₃ | MnO₂ | Cr₂O₃ | V₂O₅ |
| G1-08 | 8 | 23 | 19 | 27 | 4 | 8 | 4 | 7 |
| G1-11 | 16 | 21 | 17 | 25 | 4 | 7 | 4 | 6 |

The sample ZnO grains and the sintered powders were well mixed in a weight ratio of 100:10 and then the mixtures were used to make ZnO varistors under the same conditions as provided in Example 1, except that the sintering temperature is changed to 950° C. The varistors were tested on their varistor properties and the results are listed in Table 5.

From Table 5, the ZnO varistors have breakdown voltages ranged from 937 to 1,317 V/mm, it is learned that the ZnO varistors can be made with excellent varistor properties under low sintering temperature by using ZnO grains doped with proper species of doping ions and modifying the compositions of the sintered powder.

TABLE 5
Varistor Properties of ZnO Varistors Made of ZnO Grains Doped with
Doping Ions and Sintered powders

| | | Sinter | Silver/ | Green | | | | | | |
|---|---|---|---|---|---|---|---|---|---|---|
| | | Temp. | Reduction | Size | Grog Size | BDV | | I_{L} | Cp | Surge |
| No. | Composition | (° C.) | (° C.) | (mm) | (mm) | (V/mm) | α | (μA) | (pF) | (A) |
| 85 | Zn-X41 + | 950 | 7472/845 | 8.4 × 1.20 | 6.50 × 0.89 | 1317 | 48 | 1.1 | 29 | 206 |
| | 10% G1-08 | | | | | | | | | |
| 86 | Zn-X41 + | 950 | 7472/845 | 8.4 × 1.38 | 6.07 × 0.94 | 1079 | 40 | 1.1 | 39 | 160 |
| | 10% G1-11 | | | | | | | | | |
| 87 | Zn-X72 + | 950 | 7472/845 | 8.4 × 1.12 | 6.93 × 0.92 | 937 | 47 | 1.5 | 54 | 280 |
| | 10% G1-08 | | | | | | | | | |
| 88 | Zn-X73 + | 950 | 7472/845 | 8.4 × 1.10 | 7.00 × 0.87 | 1063 | 42 | 0.7 | 42 | 400 |
| | 10% G1-08 | | | | | | | | | |

### Example 6

The chemical coprecipitation method was used to prepare sample ZnO grains coded Zn-X144, doped with 2 mol % of Si. The sintered powder G1-08 as described in Example 5 was also prepared by means of the chemical coprecipitation method.

The sample ZnO grains and the sintered powder G1-08 were well mixed in a weight ratio of 100:5 and then the mixture was used to make ZnO varistors under the same conditions as provided in Example 1, except that the sintering temperature is changed to 1,000° C. The varistors were tested on their varistor properties and the results are listed in Table 6.

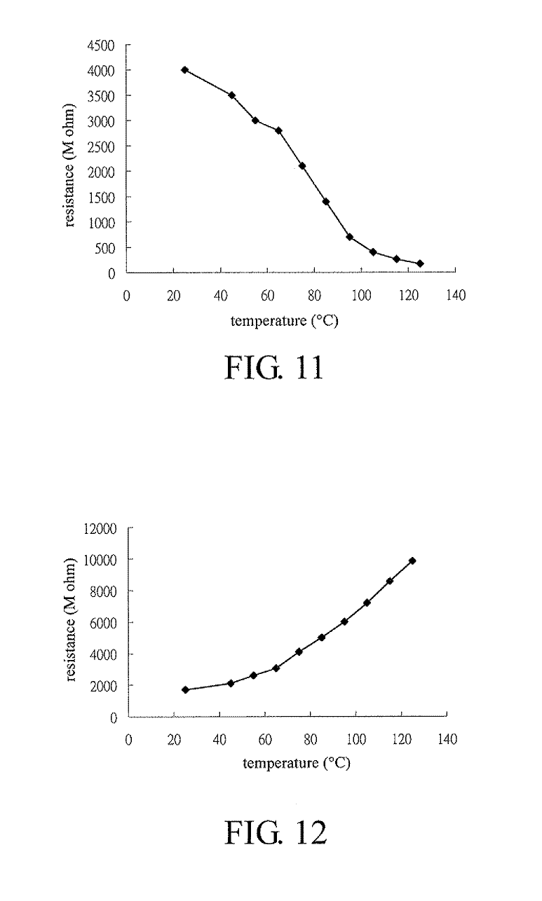

The varistors were also tested on their thermistor properties and the results are listed in Tables 7 and FIG. 11.

From Tables 6 and 7, it is learned that the ZnO varistors can be made with varistor properties and thermistor properties by using ZnO grains doped with proper species of doping ions and by modifying composition of the sintered powder. In addition, from the statistics of FIG. 11, the resultant ZnO varistors have NTC (Negative Temperature Coefficient) thermistor properties.

TABLE 6
Varistor Properties of ZnO Varistors Made of ZnO Grains Doped with Si
and G1-08 Sintered powder

| | | Sinter | Silver/ | Green | | | | | | |
|---|---|---|---|---|---|---|---|---|---|---|
| | | Temp. | Reduction | Size | Grog Size | BDV | | I_{L} | Cp | Surge |
| No. | Composition | (° C.) | (° C.) | (mm) | (mm) | (V/mm) | α | (μA) | (pF) | (A) |
| 89 | Zn-X144 + | 1000 | 7472/845 | 8.41 × 1.11 | 6.88 × 0.87 | 736 | 23 | 7.4 | 144 | 100 |
| | 5% G1-08 | | | | | | | | | |

TABLE 7
NTC Properties of ZnO Varistors Made of ZnO Grains Doped with Si
and G1-08 Sintered powder

| | 25° C. | 35° C. | 45° C. | 55° C. | 65° C. | 75° C. | 85° C. | B Value |
|---|---|---|---|---|---|---|---|---|
| Resistance | 4000 | 3800 | 3500 | 3000 | 2800 | 2100 | 1400 | 1867 |
| (M ohm) | | | | | | | | |

### Example 7

The chemical coprecipitation method was used to prepare sample ZnO grains coded Zn-X141, doped with 2 mol % of Ag. A sintered powder coded G1-38 whose composition is given below was also prepared by means of the chemical coprecipitation method.

| Sintered | Composition (wt %) | | | | | | |
|---|---|---|---|---|---|---|---|
| powder | Bi₂O₃ | B₂O₃ | Sb₂O₃ | Co₂O₃ | MnO₂ | Cr₂O₃ | V₂O₅ |
| G1-38 | 32 | 4 | 15 | 15 | 15 | 15 | 4 |

The sample ZnO grains and the sintered powder G1-38 were well mixed in a weight ratio of 100:10 and then the mixture was used to make ZnO varistors under the same conditions as provided in Example 1.

The varistor was tested on its varistor properties and the results are listed in Table 8.

The varistors were also tested on its thermistor properties and the results are listed in Table 9 and FIG. 12.

From Tables 8 and 9, it is learned that the ZnO varistors can be made with varistor properties and thermistor properties by using ZnO grains doped with proper species of doping ions and modifying composition of the sintered powder. In addition, from the statistics of FIG. 12, the resultant ZnO varistor possesses PTC (Positive Temperature Coefficient) thermistor properties.

TABLE 8
Varistor Properties of ZnO Varistors Made of ZnO Grains Doped with
Ag and G1-38 Sintered powder

| | | Sinter | Silver/ | Green | | | | | | |
|---|---|---|---|---|---|---|---|---|---|---|
| | | Temp. | Reduction | Size | Grog Size | BDV | | I_{L} | Cp | Surge |
| No. | Composition | (° C.) | (° C.) | (mm) | (mm) | (V/mm) | α | (μA) | (pF) | (A) |
| 90 | Zn-X141 + | 1060 | 7472/845 | 8.41 × 1.0 | 7.55 × 0.83 | 846 | 9 | 48 | 156 | 630 |
| | 5% G1-38 | | | | | | | | | |

TABLE 9
PTC Properties of ZnO Varistors made of ZnO Grains Doped with Ag
and G1-38 Sintered powder

| | | | | | | | | B |
|---|---|---|---|---|---|---|---|---|
| | 25° C. | 35° C. | 45° C. | 55° C. | 65° C. | 75° C. | 85° C. | Value |
| Resistance | 1700 | 2100 | 2600 | 3050 | 4100 | 5000 | 5000 | −1918 |
| (M ohm) | | | | | | | | |

### Example 8

ZnO grains of two formulas, Formula A and Formula B, were used, which were doped with different doping ions and mixed with different sintered powders. Therein, Formula A contains Zn-X144 ZnO grains of Example 6 mixed with 5% of G1-08 sintered powder. After sintering, Formula A gave strong varistor properties and considerable NTC properties (yet has high resistance at 25° C.).

Formula B contains Zn-X144 ZnO grains of Example 6 mixed with 30% of N-08 sintered powder by weight. After sintering, Formula B gave meaningful NTC properties (yet has high resistance at 25° C.) but had inferior varistor properties. Therein, N-08 has the below composition.

| | Composition (wt %) | | | | | |
|---|---|---|---|---|---|---|
| Sintered powder | Co₂O₃ | MnO₂ | Cr₂O₃ | NiO | SiO₂ | V₂O₅ |
| N-08 | 23 | 37 | 10 | 23 | 5 | 2 |

Formula A and Formula B were respectively added with a binder and a solvent, and then were ball ground and pulped so as to be made into green tapes having a thickness of 20-60 μm through a tape casting process.

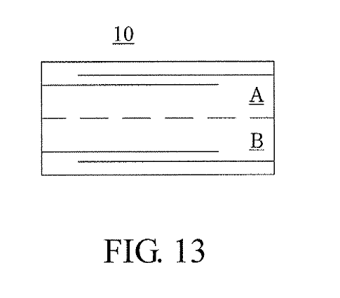

According to the know approach to making multi-layer varistors, the green tapes of Formula A and Formula B were piled up and printed with inner electrode, to form green tape 10 for the dual-function chip as shown in FIG. 13. After binder removal, the green tape 10 was placed into a sintering furnace to be heated at 900-1050° C. for 2 hours.

Then two ends of the green tape 10 were coated with silver electrode and sintered at 700-800° C. for 10 minutes to form the dual-function chip element. Measurement of electricity of the dual-function chip element indicates that the chip element possesses varistor properties and excellent NTC thermistor properties (with low resistance at room temperature).

Then electrical properties of the chip element including ESD tolerance and thermistor properties were also tested and are provided in Tables 10 and 11.

From Tables 10 and 11, it is learned that the chip element is capable of enduring 20 times of ESD 8 KV applied thereto and has 10.2K ohm of NTC thermistor properties while presenting low resistance at room temperature. The chip element is a dual-function element possessing both varistor properties and thermistor properties.

TABLE 10
Varistor Properties of Dual-Function Element Made of Two
Formulas containing ZnO grains doped with different Species
of Doping Ions and Different Sintered powders

| | | Sinter | Silver/ | Green | | | | |
|---|---|---|---|---|---|---|---|---|
| | | Temp. | Reduction | Size | Grog Size | BDV | Cp | ESD |
| No. | Composition | (° C.) | (° C.) | (mm) | (mm) | (V/mm) | (pF) | (KV) |
| 91 | Zn-X141 + 5% G1-38 | 1000 | 845 | 1.95 × 0.97 | 1.6 × 0.795 | 14 | 376 | pass |
| | Zn-X144 + 30% N-08 | | | | | | | |

TABLE 11
NTC Properties of Dual-Function Element Made of Two Formulas
containing ZnO Grains Doped with Different Species of Doping Ions
and Different Sintered powders

| | | | | | | | | B |
|---|---|---|---|---|---|---|---|---|
| | 25° C. | 35° C. | 45° C. | 55° C. | 65° C. | 75° C. | 85° C. | Value |
| Resistance (K ohm) | 10.2 | 8.6 | 7.5 | 5.4 | 4.2 | 3.3 | 2.7 | 2367 |

### Example 9

Zn-X300 ZnO grains of Table 12 were made by immersing ZnO powder of 0.6 micron into a solution containing doping ions, and drying and sintering the doped ZnO powder at 1050° C. for 5 hours, and grinding the sintered product into fine grains. Zn-X300 ZnO grains have the composition shown below:

Zn-X300 ZnO Grain

| Composition | Zn | Sn | Si | Al |
|---|---|---|---|---|
| mol % | 0.97 | 0.01 | 0.02 | 0.000075 |

The chemical coprecipitation method was used to prepare a sintered powder numbered G-200, as shown in Table 12. The composition of the sintered powder G-200 is given below:

| Sintered | Composition (wt %) | | | | | | |
|---|---|---|---|---|---|---|---|
| powder | Bi₂O₃ | Sb₂O₃ | MnO₂ | Co₂O₃ | Cr₂O₃ | Ce₂O₃ | Y₂O₃ |
| G-200 | 20 | 20 | 20 | 20 | 10 | 6 | 4 |

The sample ZnO grains and the sintered powder were well mixed in a weight ratio of 100:17.6 and then ground. The ground product was used to make ZnO varistors under the same conditions as provided in Example 1, except that the sintering temperature was changed to 980° C. and 1020° C. The resultant ZnO varistors were tested on their varistor properties and the results are listed in Table 12.

TABLE 12
Varistor Properties of Multi-Layer Varistor Made of Zn-X300 Grains
and G-200 Sintered powder

| | | Sinter | Green | | | | | | | | |
|---|---|---|---|---|---|---|---|---|---|---|---|
| | | Temp. | Size | Grog Size | BDV | | I_{L} | Cp | | Surge | ESD |
| No. | Composition | (° C.) | (mm) | (mm) | (V/mm) | α | (μA) | (pF) | Clamp | (A) | (KV) |
| 92 | Zn-X300 + | 1020 | 8.4 × 1.20 | 6.78 × 0.94 | 530 | 29 | 15 | 261 | 1.42 | 264 | 30 |
| | 17.6% G-200 | | | | | | | | | | |
| 93 | Zn-X300 + | 980 | 8.4 × 1.20 | 6.79 × 0.96 | 660 | 28 | 16 | 193 | 1.38 | 398 | 30 |
| | 17.6% G-200 | | | | | | | | | | |

### Example 10

Zn-X301 ZnO grains of Table 13 was made by immersing ZnO powder of 0.6 micron into a solution containing doping ions, and drying and calcining the doped ZnO powder at the sintering temperature of 850° C. for 30 minutes in air or in argon gas, and grinding the sintered product into fine grains. Zn-X301 ZnO grains have the composition as below:

Zn-X301 ZnO Grain

| Composition | Zn | Sn | Si | Al |
|---|---|---|---|---|
| mol % | 0.983 | 0.006 | 0.001 | 0.0003 |

The chemical coprecipitation method was used to prepare a sintered powder numbered G-201, as shown in Table 13.

The composition of G-201 sintered powder is given below:

| Sintered | Composition (wt %) | | | | | | |
|---|---|---|---|---|---|---|---|
| powder | Bi₂O₃ | Sb₂O₃ | MnO₂ | Co₂O₃ | Cr₂O₃ | Ce₂O₃ | Y₂O₃ |
| G-201 | 32 | 16 | 16 | 16 | 10 | 6 | 4 |

The sample ZnO grains and the sintered powder were well mixed in a weight ratio of 100:15 and then ground. Then, the conventional technology for making multi-layer varistors was implemented while pure silver was taken as the material for inner electrode and inner electrode printing was conducted for two or four times. The product was sintered at low temperature (sintering temperature of 850° C.) to form multi-layer varistors having 0603 specifications. Varistor properties of the multi-layer varistors made by two and four times of inner electrode printing were both measured and the results are given in Table 13.

From Table 13, it is learned that the varistor made by two times of inner electrode printing has a 30 A tolerance to surge of 8/20 μs, while the varistor made by four times of inner electrode printing has a tolerance up to 40 A against the same surge. Thus, the ZnO varistors can be made with excellent varistor properties under low sintering temperature by controlling the number of times where inner electrode printing is conducted.

TABLE 13
Properties of Multi-Layer Varistor Made by Sintering Zn-X301 + 15% G-201
at Low Temperature (Sintering Temperature at 850° C.)

| | | Ag | Sinter | | Grog | | | | | | | |
|---|---|---|---|---|---|---|---|---|---|---|---|---|
| | | Coating | Temp. | Green Size | Size | BDV | | I_{L} | Cp | | Surge | ESD |
| No. | Composition | Times | (° C.) | (mm) | (mm) | (V/mm) | α | (μA) | (pF) | Clamp | (A) | (KV) |
| 94 | Zn-X301 + | 2 | 850 | 1.95 × 0.97 | 1.6 × 0.8 | 35.5 | 33 | 1.1 | 34 | 1.38 | 30 | 8 |
| | 15% G-201 | | | | | | | | | | | |
| 95 | Zn-X301 + | 4 | 850 | 1.95 × 0.97 | 1.6 × 0.8 | 32.3 | 35 | 0.5 | 98 | 1.33 | 40 | 8 |
| | 15% G-201 | | | | | | | | | | | |

What is claimed is:

1. A process for producing zinc oxide (ZnO) varistor possessed a property of breakdown voltage (V_{1mA}) ranging from 230 to 1,730 V/mm, comprising steps of
a) independently preparing ZnO grains in advance doped with one or more species of doping ions selected by a rule of intentionally controlling the advanced doped ZnO grains sufficiently semiconductorized to a preset breakdown voltage of the zinc oxide varistor capable of ranging from 230 to 1,730 V/mm, comprising steps of:
a-1) preparing a solution containing zinc ions;
a-2) preparing a solution containing doping ions selected from the group consisting of Ag, Li, Cu, Al, Ce, Co, Cr, In, Ga, La, Y, Nb, Ni, Pr, Sb, Se, Ti, V, W, Zr, Si, B, Fe, Sn and a combination thereof;
a-3) mixing the solution containing zinc ions with the solution containing selected doping ions to obtain a co-precipitate formed through nanotechnology of a chemical coprecipitation method or a sol-gel process; and
a-4) calcining the obtained co-precipitate after repeatedly washed and dried, until doping ZnO grains doped with the selected doping ions are obtained; and wherein a doping quantity of the doping ions is less than 15 mol % of ZnO;
b) independently preparing a high-impedance sintered powder or glass powder by a rule of intentionally controlling the sintered powder or glass powder sufficiently sintered to a preset breakdown voltage of the zinc oxide varistor capable of ranging from 230 to 1,730 V/mm, comprising steps of:
b-1) preparing a mixture provided with different composition of two or more oxides selected from the group consisting of Bi₂O₃, B₂O₃, Sb₂O₃, CO₂O₃, MnO₂, Cr₂O₃, V₂O₅, ZnO, NiO, SiO₂, Ce₂O₃, Y₂O₃, nickel manganese cobalt oxide and soft ferrite or any combination thereof; and
b-2) calcining the selected mixture of Step b-1) into a high-impedance sintered powder and ground into nanosized sintered powder or glass powder;
c) well mixing the doped ZnO grains of Step a) with the nanosized high-impedance sintering powder or the glass powder of Step b) in a weight ratio ranging between 100:2 and 100:30 into a mixture; and
d) processing the mixture of Step c) with high-temperature calcination, grinding, binder adding, tape pressing, sintering, and silver electrode coating to produce the ZnO varistor having a breakdown voltage ranging from 230 to 1,730 V/mm in advance controlled in Step a) or/and Step b).

2. The process for producing zinc oxide (ZnO) varistor as defined in claim 1, wherein the doping quantity of the doping ions of Step a) is less than 10 mol % of ZnO.

3. The process for producing zinc oxide (ZnO) varistor as defined in claim 1, wherein the doping quantity of the doping ions of Step a) is less than 2 mol % of ZnO.

4. The process for producing zinc oxide (ZnO) varistor as defined in claim 1, wherein the weight ratio between the doped ZnO grains of Step a) and the nanosized high-impedance sintered powder or the glass powder of Step c) ranges between 100:5 and 100:15.

5. The process for producing zinc oxide (ZnO) varistor as defined in claim 1, wherein the mixture obtained at step b-1) provided with one of the characteristics among thermistor, inductor or capacitor properties in addition to varistor property having intentionally obtained at previous Step a).

6. The process for producing zinc oxide (ZnO) varistor as defined in claim 1, wherein a calcination temperature for performing the high-temperature calcination of Step d) ranges between 950° C. and 1100° C.

7. The process for producing zinc oxide (ZnO) varistor as defined in claim 1, wherein Step a) comprises immersing ZnO powder in a solution containing the doping ions, and drying and calcinating the immersed ZnO powder in air, in argon gas, or in a gas containing hydrogen or carbon monoxide to produce the ZnO grains doped with one or more said ions.

8. The process for producing zinc oxide (ZnO) varistor as defined in claim 7, wherein a calcination temperature for performing the high-temperature calcination of Step d) is 850° C.
